(19) United States
(12) Patent Application Publication
(10) Pub. No.: US 2024/0200187 A1
(43) Pub. Date: Jun. 20, 2024

(54) METHOD FOR FORMING HIGH-QUALITY FILM BY CVD PROCESS

(71) Applicant: Piotech Inc., Shenyang (CN)

(72) Inventors: Tiezhu Xu, Shenyang (CN); Dan Li, Shenyang (CN)

(21) Appl. No.: 18/529,378

(22) Filed: Dec. 5, 2023

Related U.S. Application Data
(60) Provisional application No. 63/430,404, filed on Dec. 6, 2022.

(51) Int. Cl. C23C 16/40; C23C 16/448; C23C 16/56

(52) U.S. Cl. CPC C23C 16/401; C23C 16/448; C23C 16/56

(57) ABSTRACT

This application relates to a method for forming a high-quality film by a CVD process. Specifically, this application provides a method for depositing a flowable film on a substrate. The method includes: introducing an organosilicon precursor into a deposition chamber, where the deposition chamber includes the substrate; generating at least one nitrogen-containing free radical in remote plasma; introducing the nitrogen-containing free radical into the deposition chamber; reacting the nitrogen-containing free radical with the organosilicon precursor to generate a polysilazane chain, where the polysilazane chain is deposited on the substrate and flowable on the surface of the substrate, thereby forming the flowable film. According to the method of this application, the polysilazane chain can be generated and flowable on the surface of the substrate, thereby forming the flowable film. The flowable film can quickly fill the voids or gaps, thereby avoiding the formation of permanent defects in the voids or gaps.

### BACKGROUND

### 1. Field of the Invention

This application relates to the field of semiconductor device manufacturing, and in particular relates to a method for forming a high-quality film by a CVD process.

### 2. Description of the Related Art

When a semiconductor device is manufactured, an element is often isolated by using a shallow trench isolation structure. In an isolation region of a semiconductor substrate, the shallow trench isolation structure includes a trench or a clearance, into which a dielectric material can fill to prevent electrical coupling of nearby device structures (e.g., transistors, diodes and the like). With the development of technology, the size of the semiconductor device is becoming smaller and smaller, but more and more elements (e.g., transistors, capacitors, diodes and the like) are required thereon, which puts higher demands on manufacturing of semiconductors. One of the problems in previous manufacturing technologies is that it is difficult to fill the trench or clearance of the shallow trench isolation structure without creating voids or gaps. The presence of voids or gaps may have adverse effects on the subsequent manufacturing of the semiconductor device, for example, resulting in uneven etching, polishing, annealing and the like. If there are the voids or gaps in a finished product of the semiconductor device, the performance of the semiconductor device can be adversely affected, e.g., dielectric quality, electrical crosstalk, charge leakage, short circuit and the like.

There have been some technologies to reduce the formation of the voids or gaps, for example, to reduce the deposition rate of the dielectric material and the like, but these methods will reduce the production efficiency and yield. Another method for controlling the formation of the voids or gaps is to increase the flowability of the deposited dielectric material. Materials with high flowability are conducive to quickly filling the voids or gaps to avoid the formation of permanent defects in the voids or gaps. However, commonly used flowable films (e.g., spin-coated glass films) have lower density and are unstable.

In view of this, it is indeed necessary to provide an improved method for forming a flowable film by a CVD process, thereby forming a high-quality film.

### SUMMARY OF THE INVENTION

This application provides a method for depositing a film on a substrate to attempt to solve at least one problem in the related art to at least some extent.

According to one aspect of this application, this application provides a method for depositing a flowable film on a substrate, the method including:
introducing an organosilicon precursor into a deposition chamber, the deposition chamber including a substrate;
generating at least one nitrogen-containing free radical in remote plasma;
introducing the nitrogen-containing free radical into the deposition chamber; and
reacting the nitrogen-containing free radical with the organosilicon precursor to generate a polysilazane chain, the polysilazane chain being deposited on the substrate and being flowable on the surface of the substrate, thereby forming the flowable film.

According to an embodiment of this application, the polysilazane chain includes an Si—N bond.

According to an embodiment of this application, the organosilicon precursor reacts with the nitrogen-containing free radical to form a silicon nitrogen free radical, the silicon nitrogen free radical polymerizing to form the polysilazane chain.

According to an embodiment of this application, the polysilazane chain has

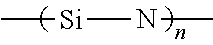

repeating units, where n is 2 to 50.

According to an embodiment of this application, the average molecular weight of the polysilazane chain is 40 to 1000 g/mol.

According to an embodiment of this application, the organosilicon precursor has at least one of formulas I, II, III, and IV:

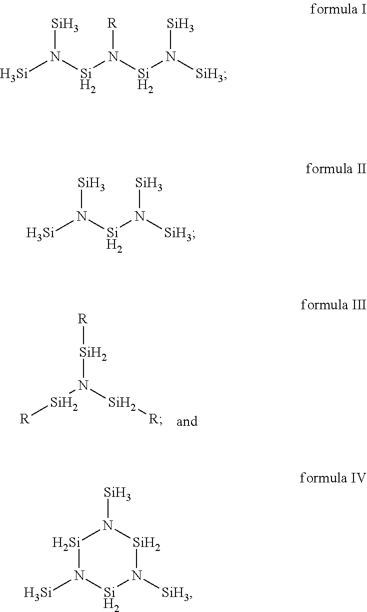

where R is independently selected from hydrogen, halogen, linear C₁-C₁₀ alkyl, branched C₃-C₁₀ alkyl, linear or branched C₃-C₁₂ alkenyl, linear or branched C₃-C₁₀ alkynyl, C₄-C₁₀ cycloalkyl, or C₆-C₁₀ aryl.

According to an embodiment of this application, when the organosilicon precursor has formula I, the polysilazane chain has at least one of formulas 1-1, 1-2, and 1-3:

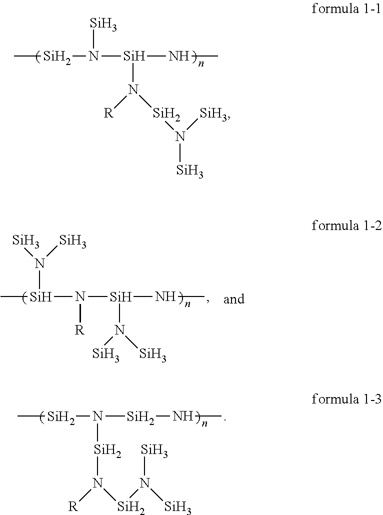

According to an embodiment of this application, when the organosilicon precursor has formula II, the polysilazane chain has at least one of formulas 2-1 and 2-2:

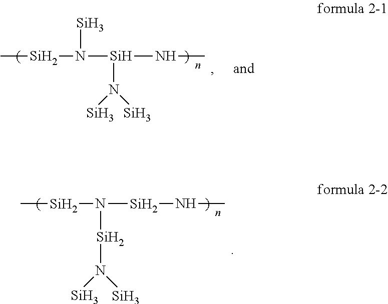

According to an embodiment of this application, when the organosilicon precursor has formula III, the polysilazane chain has formula 3:

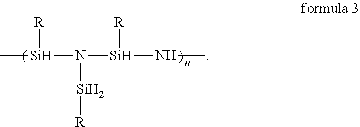

According to an embodiment of this application, when the organosilicon precursor has formula IV, the polysilazane chain has at least one of formulas 4-1 and 4-2:

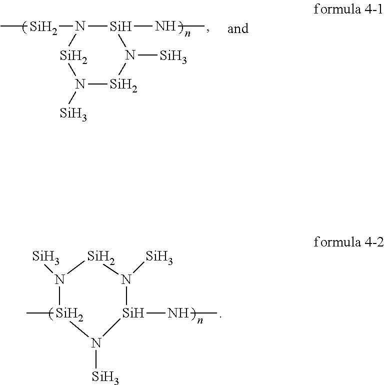

According to an embodiment of this application, the method further includes exposing ammonia in the remote plasma to generate the nitrogen-containing free radical.

According to an embodiment of this application, the nitrogen-containing free radical has the chemical formula NHx, x being 0, 1, or 2.

According to another aspect of this application, this application provides a method for forming a film on a substrate, the method including:
introducing an organosilicon precursor into a deposition chamber, the deposition chamber including a substrate;
generating at least one nitrogen-containing free radical in remote plasma; introducing the nitrogen-containing free radical into the deposition chamber;
reacting the nitrogen-containing free radical with the organosilicon precursor to produce a polysilazane chain, the polysilazane chain being deposited on the substrate and being flowable on the surface of the substrate, thereby forming the flowable film;
curing the flowable film; and
annealing the cured flowable film to form the film, the film including multiple Si—O—Si bonds.

According to an embodiment of this application, the flowable film is formed by the method according to this application.

According to an embodiment of this application, the curing the flowable film includes at least one of:
(a) exposing the flowable film to ozone and water; and
(b) exposing the flowable film to the ozone and ultraviolet rays; and

According to an embodiment of this application, the curing the flowable film includes exposing the flowable film to the ozone and the water at temperature of 150° C. to 450° C. and at pressure of 400 Torr to 800 Torr.

According to an embodiment of this application, the curing the flowable film includes exposing the flowable film to the ozone at temperature of less than 100° C. and at pressure of 400 Torr to 800 Torr, and then exposing the same to the ultraviolet rays at pressure of less than 150 Torr.

According to an embodiment of this application, the annealing the cured flowable film includes performing the annealing in an atmosphere of nitrogen at temperature of 1050° C.

According to an embodiment of this application, the annealing the cured flowable film includes performing the annealing in an atmosphere of vapor at temperature of 200° C. to 600° C.

According to an embodiment of this application, the vapor includes at least one of water vapor and acid vapor.

According to an embodiment of this application, the method includes performing the annealing in an atmosphere of the water vapor to form at least a first portion of the Si—O—Si bond.

According to an embodiment of this application, the method includes performing the annealing in an atmosphere of the acid vapor to form at least a second portion of the Si—O—Si bond.

According to an embodiment of this application, the acid vapor includes hydrochloric acid or acetic acid.

According to an embodiment of this application, the film is a silicon oxide film.

According to an embodiment of this application, the density of the film is greater than that of the flowable film.

According to the method of this application, the polysilazane chain can be generated by the CVD process, and is flowable on the surface of the substrate, thereby forming the flowable film. The flowable film can quickly fill the voids or gaps, thereby avoiding the formation of permanent defects in the voids or gaps. Through curing and annealing processes, the flowable film can be formed into the high-quality film.

The additional aspects and advantages of this application will be partially described, shown, or explained by the implementation of the embodiments of this application in subsequent description.

### BRIEF DESCRIPTION OF THE DRAWINGS

A brief description of the drawings necessary to describe the embodiments of this application or the prior art will be provided below to facilitate the description of the embodiments of this application. Obviously, the drawings in the following description are only some embodiments of this application. For those skilled in the art, without the need for creative labor, drawings of other embodiments can still be obtained according to the structures illustrated in such drawings.

FIG. 1 shows a simplified flowchart of a method for depositing a film on a substrate according to an embodiment of this application.

FIG. 2 shows another simplified flowchart of a method for depositing a film on a substrate according to an embodiment of this application.

FIG. 3 shows a chemical reaction mechanism of forming a polysilazane chain from a trimethylsilylamine (TSA) precursor and a nitrogen-containing free radical generated by decomposition of ammonia in remote plasma according to an embodiment of this application.

FIG. 4 shows a reaction flowchart of a method for depositing a silicon oxide film on a substrate according to an embodiment of this application.

### DETAILED DESCRIPTION OF THE INVENTION

The embodiments of this application will be described in detail below. The embodiments of this application shall not be construed as limiting this application.

In PREFERRED EMBODIMENT OF THE PRESENT INVENTION and the patent application scope, the list of items connected by the term “at least one of”' may refer to any combination of the listed items. For example, if items A and B are listed, the phrase “at least one of A and B” means only A; only B; or A and B. In another example, if items A, B, and C are listed, the phrase “at least one of A, B, and C” means only A; or only B; only C; A and B (excluding C); A and C (excluding B); B and C (excluding A); or all of A, B, and C. Item A may include a single element or multiple elements. Item B may include a single element or multiple elements. Item C may include a single element or multiple elements.

The term “alkyl” is expected to be a linear saturated hydrocarbon structure with 1 to 10 carbon atoms. The “alkyl” is also expected to be a branched or cyclic hydrocarbon structure with 3 to 10 carbon atoms. When an alkyl with a specific carbon number is specified, it is expected to encompass all geometric isomers with that carbon number. Thus, for example, “butyl” means including n-butyl, sec-butyl, isobutyl, tert-butyl and cyclobutyl; “propyl” includes n-propyl, isopropyl and cyclopropyl. Examples of the alkyl include, but are not limited to, methyl, ethyl, n-propyl, isopropyl, cyclopropyl, n-butyl, isobutyl, sec-butyl, tert-butyl, cyclobutyl, n-pentyl, isopentyl, neopentyl, cyclopentyl, methylcyclopentyl, ethylcyclopentyl, n-hexyl, cyclohexyl, cyclohexyl, n-heptyl, octyl, cyclopropyl, cyclobutyl, norbornyl and the like.

The term “alkenyl” refers to a univalent unsaturated hydrocarbon group that may be of a linear or branched chain and has at least one and typically one, two, or three carbon-carbon double bonds. Unless otherwise defined, the alkenyl typically contains 3 to 12 carbon atoms and includes (for example) —C₂-₄ alkenyl, —C₂-₆ alkenyl, and —C₂-₁₀ alkenyl. Representative alkenyls include (for example) vinyl, n-propenyl, isopropenyl, n-but-2-enyl, but-3-enyl, n-hex-3-enyl and the like.

The term “alkynyl” refers to a univalent unsaturated hydrocarbon group that may be of a linear or branched chain and has at least one and typically has one, two, or three carbon-carbon triple bonds. Unless otherwise defined, the alkynyl typically contains 3 to 12 carbon atoms and includes (for example) —C₂-₄ alkynyl, —C₃-₆ alkynyl, and —C₃-₁₀ alkynyl. Representative alkynyls include (for example) ethynyl, prop-2-alkynyl (n-propynyl), n-but-2-alkynyl, n-hex-3-alkynyl and the like.

The term “cycloalkyl” refers to non-aromatic monocyclic or polycyclic hydrocarbyl consisting only of carbon and hydrogen atoms, where the hydrocarbyl may include a fused or bridged ring system, may have 3 to 15 carbon atoms, preferably 4 to 10 carbon atoms, and may be saturated or unsaturated. Monocyclic groups include, for example, cyclopropyl, cyclobutyl, cyclopentyl, cyclohexyl, cycloheptyl, cyclooctyl and the like. Polycyclic groups include, for example, adamantine, norbornane, decahydronaphthyl, 7,7-dimethyl bicyclic [2.2.1] heptyl and the like.

The term “aryl” refers to a monovalent aromatic hydrocarbon with a single ring (e.g. phenyl) or fused ring. The fused ring system includes those completely unsaturated ring systems (e.g., naphthalene) and those partially unsaturated ring systems (e.g., 1,2,3,4-tetrahydronaphthalene). Unless otherwise defined, the aryl typically contains 6 to 10 carbon atoms and includes (for example) —C₆-₁₀ aryl. Representative aryls include, for example, phenyl, methylphenyl, propylphenyl, isopropylphenyl, benzyl, and naphthalen-1-yl, naphthalen-2-yl and the like.

This application provides a method for depositing a flowable film on a substrate, including:
introducing an organosilicon precursor into a deposition chamber, where the deposition chamber includes a substrate;
generating at least one nitrogen-containing free radical in remote plasma;
introducing the nitrogen-containing free radical into the deposition chamber; and
reacting the nitrogen-containing free radical with the organosilicon precursor to generate a polysilazane chain, where the polysilazane chain is deposited on the substrate and is flowable on the surface of the substrate, thereby forming the flowable film.

In some embodiments, the polysilazane chain includes an Si-N bond.

In some embodiments, the organosilicon precursor reacts with the nitrogen-containing free radical to form a silicon nitrogen free radical, the silicon nitrogen free radical polymerizing to form the polysilazane chain. The nitrogen-containing free radical, as a polymerization chain initiator, can react with the organosilicon precursor to form a silicon-nitrogen small molecule free radical. The silicon-nitrogen small molecule free radical continuously reacts with the nitrogen-containing free radical to realize the polymerization growth of the chain, finally forming the polysilazane chain.

In some embodiments, the polysilazane chain has

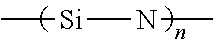

repeating units, where n is 2 to 50. In some embodiments, n is 5 to 40. In some embodiments, n is 10 to 30. In some embodiments, n is 10 to 20.

In some embodiments, the average molecular weight of the polysilazane chain is 40 to 1000 g/mol. In some embodiments, the average molecular weight of the polysilazane chain is 50 to 800 g/mol. In some embodiments, the average molecular weight of the polysilazane chain is 100 to 500 g/mol. In some embodiments, the average molecular weight of the polysilazane chain is 200 to 400 g/mol.

In some embodiments, the organosilicon precursor has at least one of formulas I, II, III, and IV:

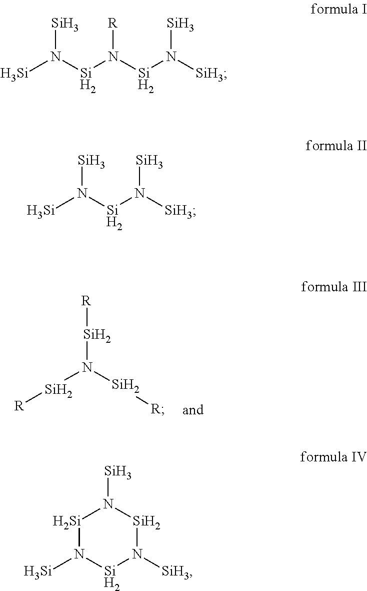

where R is independently selected from hydrogen, halogen, linear C₁-C₁₀ alkyl, branched C₃-C₁₀ alkyl, linear or branched C₃-C₁₂ alkenyl, linear or branched C₃-C₁₂ alkynyl, C₄-C₁₀ cycloalkyl, or C₆-C₁₀ aryl.

In some embodiments, the organosilicon precursor is trimethylsilylamine (TSA):

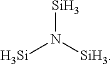

In some embodiments, the method further includes exposing ammonia in the remote plasma to generate the nitrogen-containing free radical. The plasma conditions used for decomposing the ammonia into the nitrogen-containing free radical include: using RF power ranging from 3 kW to 15 kW to generate plasma at room pressure ranging from 1 Torr to 10 Torr, and at temperature ranging from room temperature to about 200° C.

In some embodiments, the nitrogen-containing free radical has the chemical formula NHₓ, where x is 0, 1, or 2. Decomposition of the ammonia in a remote plasma system can generate the nitrogen-containing free radical, including N, NH, or NH₂.

In some embodiments, when the organosilicon precursor has formula 1, the polysilazane chain has at least one of formulas 1-1, 1-2, and 1-3:

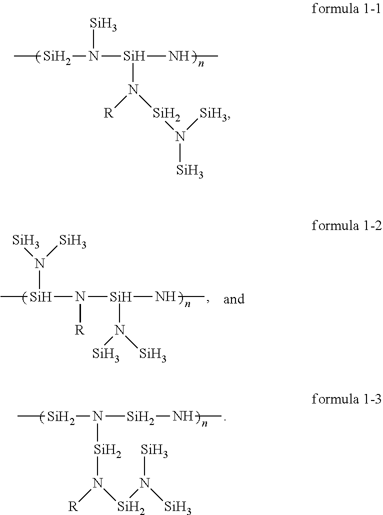

In some embodiments, when the organosilicon precursor has formula II, the polysilazane chain has at least one of formulas 2-1 and 2-2:

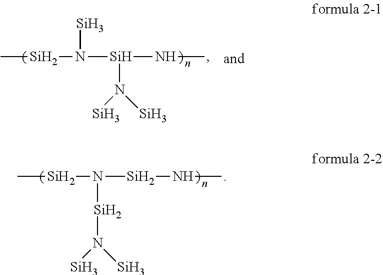

In some embodiments, when the organosilicon precursor has formula III, the polysilazane chain has formula 3:

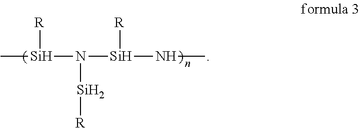

5 In some embodiments, when the organosilicon precursor has formula IV, the polysilazane chain has at least one of formulas 4-1 and 4-2:

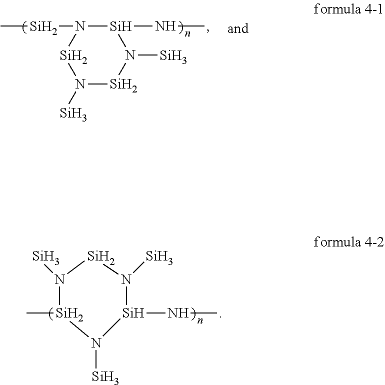

The chemical vapor deposition (CVD) process is employed in this application, such that the organosilicon precursor reacts with at least one nitrogen-containing free radical (such as —N, —NH, —NH₂) generated in the remote plasma to generate the polysilz [symbol] where the polysilazane chain includes the Si—N bond. The polysilazane chain has

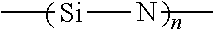

repeating units, and its backbone does not contain carbon or oxygen atoms, which helps to improve the flowability of the formed film on the substrate, and thereby, the trench or clearance in the substrate can be quickly and effectively filled.

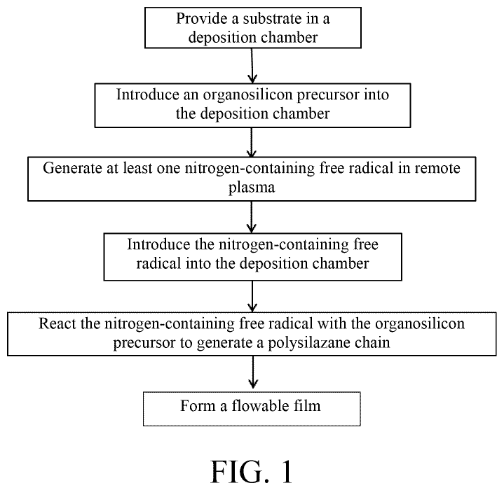

The order in which the organosilicon precursor and the nitrogen-containing free radical are introduced into the deposition chamber is not limited. FIG. 1 shows a simplified flowchart of a method for depositing a film on a substrate according to an embodiment of this application, where after the substrate is provided in the deposition chamber, the organosilicon precursor is firstly introduced into the deposition chamber, and then at least one nitrogen-containing free radical generated in the remote plasma is introduced into the deposition chamber. The organosilicon precursor and the at least one nitrogen-containing free radical react to generate the polysilazane chain, and the flowable film is formed.

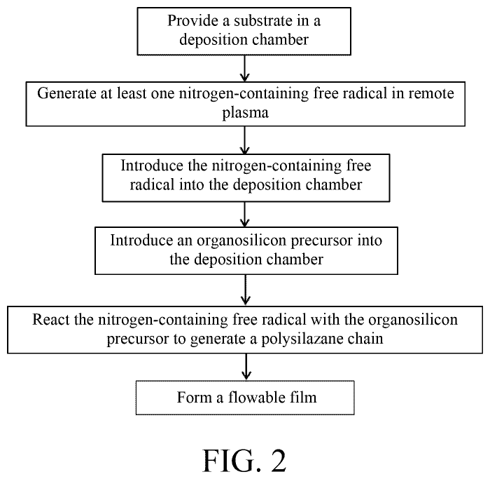

FIG. 2 shows another simplified flowchart of a method for depositing a film on a substrate according to an embodiment of this application, where after the substrate is provided in the deposition chamber, at least one nitrogen-containing free radical generated in the remote plasma is firstly introduced into the deposition chamber, and then the organosilicon precursor is introduced into the deposition chamber. The at least one nitrogen-containing free radical and the organosilicon precursor react to generate the polysilazane chain, and the flowable film is formed.

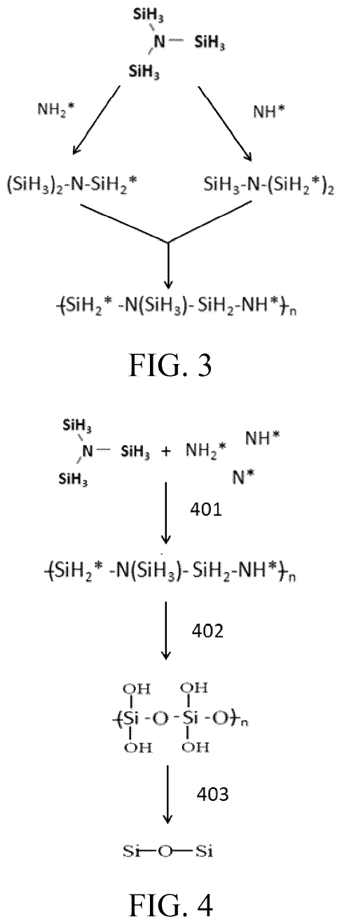

FIG. 3 shows chemical reaction steps of forming a polysilazane chain from a trimethylsilylamine (TSA) precursor and a nitrogen-containing free radical generated by decomposition of ammonia in remote plasma according to an embodiment of this application. As shown, after TSA meet N, NH and NH₂ free radicals generated by ammonia decomposition in the deposition chamber, a silicon nitrogen (—Si—N—) free radical is generated, and the silicon nitrogen (—Si—N—) free radical undergoes a polymerization reaction to form the polysilazane chain, and the flowable film is formed. Other types of silicon-containing precursors can react with the nitrogen-containing free radicals according to a similar mechanism to form the polysilazane chain.

The CVD process can be carried out under the following processing conditions: the flow rate of the precursor is set to 100 to 1000 sccm; the deposition chamber is maintained at pressure ranging from about 1 mTorr to about 600 Torr; and the room temperature is controlled to be between about 0° C. and about 400° C.

This application also provides a method for depositing a film on a substrate, including:
introducing an organosilicon precursor into a deposition chamber, where the deposition chamber includes a substrate;
generating at least one nitrogen-containing free radical in remote plasma;
introducing the nitrogen-containing free radical into the deposition chamber;
reacting the nitrogen-containing free radical with the organosilicon precursor to produce a polysilazane chain, where the polysilazane chain is deposited on the substrate and is flowable on the surface of the substrate, thereby forming the flowable film;
curing the flowable film; and
annealing the cured flowable film to form the film, where the film includes multiple Si—O—Si bonds.

FIG. 4 shows a reaction flowchart of a method for depositing a silicon oxide film on a substrate according to an embodiment of this application, where step 401 shows the formation process of the polysilazane chain, and the formed polysilazane chain has high flowability; step 402 shows the curing process, during which an N atom in the polysilazane chain is replaced by an O atom, thereby increasing the stability of the film and forming a structurally stable and non-flowable film; and step 403 shows the annealing process, during which an H atom in the film is removed to form the silicon oxide film. According to the method of this application, high-quality films can be obtained, including, but not limited to, silicon oxide films, silicon nitride films, silicon oxide nitride films, carbon-doped silicon nitride films or carbon-doped silicon oxide films. Therefore, the high-quality films can be widely used in the manufacturing of various semiconductor devices.

In some embodiments, the flowable film is formed by the method according to this application.

In some embodiments, the curing the flowable film includes at least one of:
(a) exposing the flowable film to ozone and water; and
(b) exposing the flowable film to the ozone and ultraviolet rays; and

In some embodiments, the curing the flowable film includes exposing the flowable film to the ozone and the water at temperature of 150° C. to 450° C. and at pressure of 400 Torr to 800 Torr.

In some embodiments, the curing the flowable film includes exposing the flowable film to the ozone and the water at temperature of 150° C. and at pressure of 600 Torr.

In some embodiments, the curing the flowable film includes exposing the flowable film to the ozone at temperature of less than 100° C. and at pressure of 400 Torr to 800 Torr, and then exposing the same to the ultraviolet rays at pressure of less than 150 Torr. In some embodiments, the curing the flowable film includes exposing the flowable film to the ozone at temperature of 25° C. to 100° C. and at pressure of 600 Torr, and then exposing the same to the ultraviolet rays at pressure of 50 Torr to 150 Torr.

In some embodiments, the annealing the cured flowable film includes performing the annealing in an atmosphere of nitrogen at temperature of 1050° C.

In some embodiments, the annealing the cured flowable film includes performing the annealing in an atmosphere of vapor at temperature of 200° C.to 600° C.

In some embodiments, the vapor includes at least one of water vapor and acid vapor.

In some embodiments, the method includes performing the annealing in an atmosphere of the water vapor to form at least a first portion of the Si—O—Si bond.

In some embodiments, the method includes performing the annealing in an atmosphere of the acid vapor to form at least a second portion of the Si—O—Si bond.

After two times of annealing, H can be completely removed from the cured flowable film, further improving the quality of the film.

In some embodiments, the acid vapor includes hydrochloric acid or acetic acid.

In some embodiments, the film is a silicon oxide film.

In some embodiments, the density of the film is greater than that of the flowable film.

The formation method of the film will be illustrated below with only taking the silicon oxide film as an example and in conjunction with specific embodiments. Those skilled in the art will understand that the method and film described in this application are only examples, and any other suitable methods and films can be applied.

### Example:

Firstly, a substrate was provided in a deposition chamber, and trimethylsilylamine (TSA) was introduced into the deposition chamber. Subsequently, a remote plasma source was used. RF power ranging from 3 kW to 15 KW is employed to generate plasma at room pressure ranging from 1 Torr to 10 Torr, and at temperature ranging from room temperature to about 200° C. Ammonia was decomposed in the plasma to generate H, NH, and NH₂ free radicals, and these free radicals were introduced into the deposition chamber. In the deposition chamber, TSA underwent a polymerization reaction with the free radicals to generate the polysilazane chain in a gas-phase environment, and a thin film was condensed on the substrate. The thin film was flowable on the surface of the substrate, thereby forming the flowable film. Subsequently, the flowable film was exposed to ozone and ultraviolet rays to be cured. Next, annealing was carried out at temperature ranging from 20° C. to 900° C.to obtain a silicon oxide film.

The references to “an embodiment”, “some of embodiments”, “one embodiment”, “another example”, “an example”, “a specific example” or “some of examples” throughout the entire description mean that at least one embodiment or example in this application includes the specific features, structures, materials, or characteristics described in that embodiment or example. Therefore, the descriptions throughout the entire description, such as “in some embodiments”, “in an embodiment”, “in one embodiment”, “in another example”, “in one example”, “in a specific example”, or “an example”, do not necessarily refer to the same embodiment or example in this application. Furthermore, the specific features, structures, materials, or characteristics herein can be combined in any suitable way in one or more embodiments or examples.

Although illustrative embodiments have been demonstrated and described, those skilled in the art should understand that the aforementioned embodiments cannot be interpreted as limiting this application, and can be changed, replaced, and modified without departing from the spirit, principle, and scope of this application. AMENDMENTS TO THE CLAIMS

1. A method for depositing a flowable film on a substrate, comprising:
introducing an organosilicon precursor into a deposition chamber, the deposition chamber comprising a substrate;
generating at least one nitrogen-containing free radical in remote plasma;
introducing the nitrogen-containing free radical into the deposition chamber; and
reacting the nitrogen-containing free radical with the organosilicon precursor to generate a polysilazane chain, the polysilazane chain being deposited on the substrate and being flowable on the surface of the substrate, thereby forming the flowable film.

2. The method according to claim 1, wherein the polysilazane chain comprises an Si—N bond.

3. The method according to claim 1, wherein the organosilicon precursor reacts with the nitrogen-containing free radical to form a silicon nitrogen free radical, the silicon nitrogen free radical polymerizing to form the polysilazane chain.

4. The method according to claim 1, wherein the polysilazane chain has 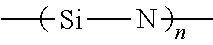
repeating units, wherein n is 2 to 50.

5. The method according to claim 1, wherein the average molecular weight of the polysilazane chain is 40 to 1000 g/mol.

6. The method according to claim 1, wherein the organosilicon precursor has at least one of formulas I, II, III, and IV: 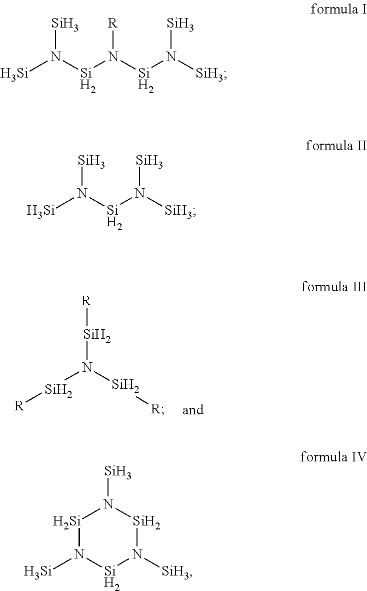
wherein R is independently selected from hydrogen, halogen, linear C₁-C₁₀ alkyl, branched C₃-C₁₀ alkyl, linear or branched C₃-C₁₂ alkenyl, linear or branched C₃-C₁₂ alkynyl, C₄-C₁₀ cycloalkyl, or C₆-C₁₀ aryl.

7. The method according to claim 6, wherein:
(i) when the organosilicon precursor has formula I, the polysilazane chain has at least one of formulas 1-1, 1-2, and 1-3: 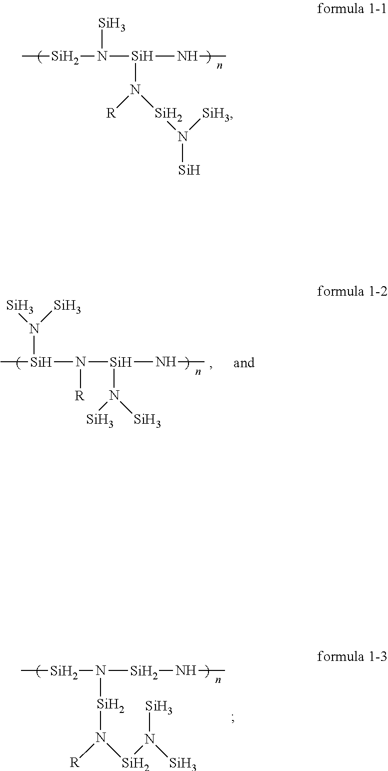
(ii) when the organosilicon precursor has formula II, the polysilazane chain has at least one of formulas 2-1, and 2-2: 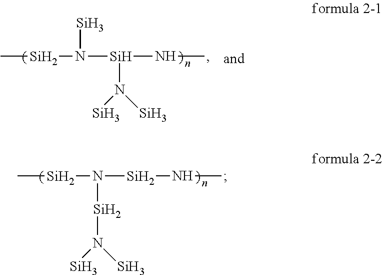
(iii) when the organosilicon precursor has III, the polysilazane chain has formula 3: 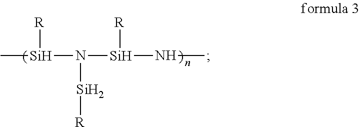
(iv) when the organosilicon precursor has formula IV, the polysilazane chain has at least one of formulas 4-1, and 4-2:

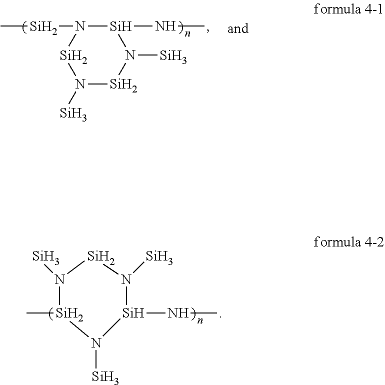

8. The method according to claim 1, wherein the method further comprises exposing ammonia in the remote plasma to generate the nitrogen-containing free radical.

9. The method according to claim 1, wherein the nitrogen-containing free radical has the chemical formula NHₓ, x is 0, 1, or 2.

10. A method for depositing a film on a substrate, comprising:
introducing an organosilicon precursor into a deposition chamber, the deposition chamber comprising a substrate;
generating at least one nitrogen-containing free radical in remote plasma;
introducing the nitrogen-containing free radical into the deposition chamber;
reacting the nitrogen-containing free radical with the organosilicon precursor to produce a polysilazane chain, the polysilazane chain being deposited on the substrate and being flowable on the surface of the substrate, thereby forming the flowable film;
curing the flowable film; and
annealing the cured flowable film to form the film, the film comprising multiple Si-O-Si bonds.

11. (canceled)

12. The method according to claim 10, wherein the curing the flowable film comprises at least one of:
(a) exposing the flowable film to ozone and water; and
(b) exposing the flowable film to the ozone and ultraviolet rays.

13. The method according to claim 12, wherein the curing the flowable film comprises exposing the flowable film to the ozone and the water at temperature of 150° C. to 450° C. and at pressure of 400 Torr to 800 Torr.

14. The method according to claim 12, wherein the curing the flowable film comprises exposing the flowable film to the ozone at temperature of less than 100° C. and at pressure of 400 Torr to 800 Torr, and then exposing the same to the ultraviolet rays at pressure of less than 150 Torr.

15. The method according to claim 10, wherein the annealing the cured flowable film comprises performing the annealing in an atmosphere of nitrogen at temperature of 1050° C.

16. The method according to claim 10, wherein the annealing the cured flowable film comprises performing the annealing in an atmosphere of vapor at temperature of 200° C.to 600° C.

17. The method according to claim 16, wherein the vapor comprises at least one of water vapor and acid vapor.

18. The method according to claim 17, wherein the method comprises performing the annealing in an atmosphere of the water vapor to form at least a first portion of the Si-O-Si bond.

19. The method according to claim 18, wherein the method comprises performing the annealing in an atmosphere of the acid vapor to form at least a second portion of the Si-O-Si bond.

20. The method according to claim 17, wherein the acid vapor comprises hydrochloric acid or acetic acid.

21. The method according to claim 10, wherein the film is a silicon oxide film.

22. The method according to claim 10, wherein the density of the film is greater than that of the flowable film.
